(19) United States
(12) Patent Application Publication
(10) Pub. No.: US 2026/0009132 A1
(43) Pub. Date: Jan. 8, 2026

(54) DEPOSITION APPARATUS AND METHOD FOR OPERATING THE SAME

(71) Applicant: TAIWAN SEMICONDUCTOR MANUFACTURING COMPANY, LTD., Hsinchu (TW)

(72) Inventors: Tuoh Bin NG, Taoyuan City (TW); Sagar Deepak KHIVSARA, Hsinchu City (TW)

(73) Assignee: TAIWAN SEMICONDUCTOR MANUFACTURING COMPANY, LTD., Hsinchu (TW)

(21) Appl. No.: 18/764,875

(22) Filed: Jul. 5, 2024

(51) Int. Cl. C23C 16/455; C23C 16/458; H01L 21/02

(52) U.S. Cl. CPC C23C 16/45565; C23C 16/45591; C23C 16/4584; H01L 21/02576; H01L 21/0262

(57) ABSTRACT

A method includes introducing a semiconductor-containing precursor gas into a reaction chamber through a gas passage; directing the semiconductor-containing precursor gas from the gas passage to a region over a shower plate, wherein the shower plate is above the gas passage and a wafer in the reaction chamber; guiding the semiconductor-containing precursor gas to flow through the shower plate; rotating the wafer; and epitaxially growing an epitaxy feature over the wafer by using the semiconductor-containing precursor gas to interact with the wafer when rotating the wafer.

### BACKGROUND

Semiconductor structures, such as sources, drains, and gates, are often deposited using chemical vapor deposition (CVD) or other similar deposition processes. Accordingly, the structures may be formed by growing a film on the surface of a semiconductor wafer. In order to perform CVD, the wafer is generally mounted on a susceptor. The film is deposited on the wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic cross-sectional view of a deposition apparatus according to some embodiments of the present disclosure.

FIG. 1B is a schematic top view of the deposition apparatus of FIG. 1A.

FIG. 1C is a schematic view of a portion of a deposition apparatus according to some embodiments of the present disclosure.

FIG. 1D is a schematic view of a portion of a deposition apparatus according to some embodiments of the present disclosure.

FIG. 2 shows vectors of gas flows during a deposition process according to some embodiments of the present disclosure.

FIGS. 3A-3D are schematic cross-sectional views of a semiconductor device during various stage of manufacture according to some embodiments of the present disclosure.

FIG. 4 is a schematic view of a portion of a deposition apparatus according to some embodiments of the present disclosure.

FIG. 5 is a schematic view of a portion of a deposition apparatus according to some embodiments of the present disclosure.

FIG. 6 is a schematic view of a portion of a deposition apparatus according to some embodiments of the present disclosure.

FIG. 7 is a schematic view of a portion of a deposition apparatus according to some embodiments of the present disclosure.

FIG. 8 is a schematic view of a portion of a deposition apparatus according to some embodiments of the present disclosure.

FIG. 9 is a schematic view of a portion of a deposition apparatus according to some embodiments of the present disclosure.

FIG. 10 is a diagram illustrating relative gas concentration distributions on a wafer according to some embodiments of the present disclosure.

FIG. 11A is a schematic cross-sectional view of a deposition apparatus according to some embodiments of the present disclosure.

FIG. 11B is a schematic top view of the deposition apparatus of FIG. 11A.

FIG. 12 shows pulses versus time in a deposition process according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

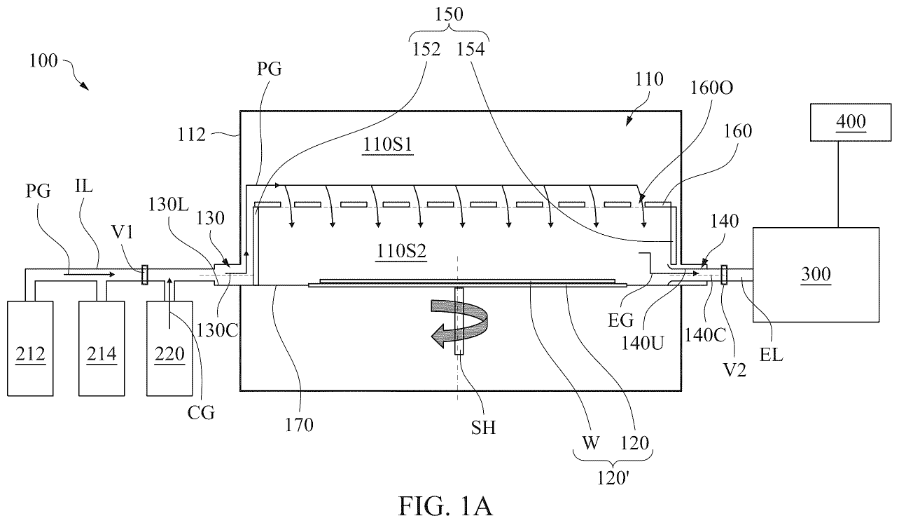

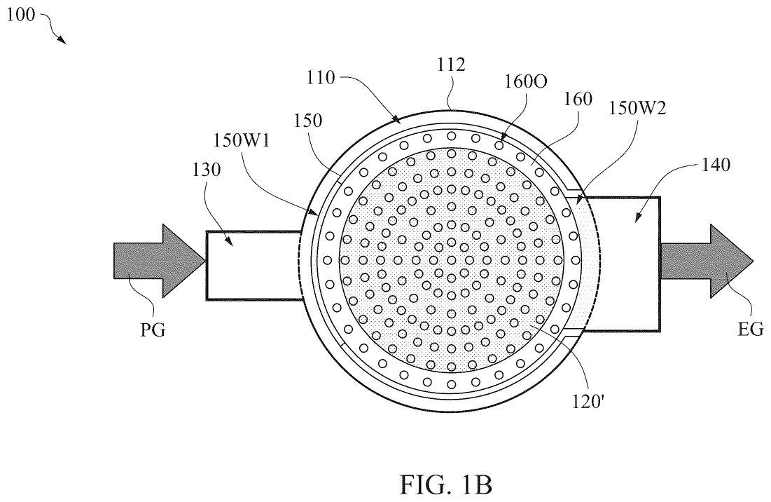

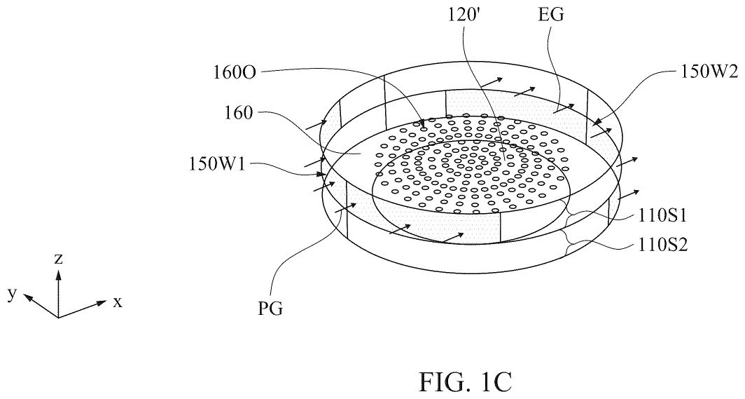

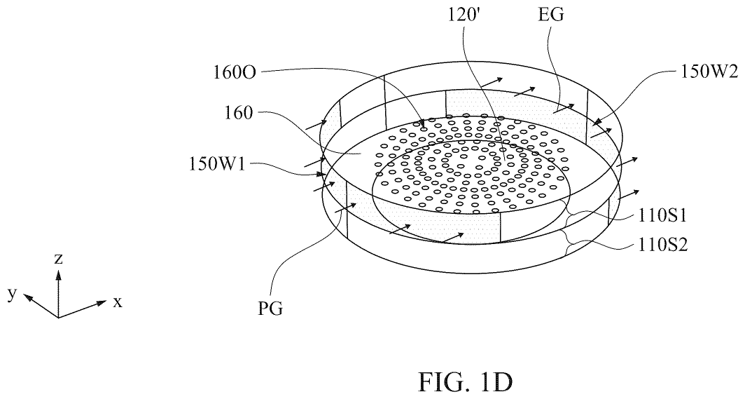

FIG. 1A is a schematic side view of a deposition apparatus 100 according to some embodiments of the present disclosure. FIG. 1B is a schematic top view of the deposition apparatus 100 of FIG. 1A. The deposition apparatus 100 may be a reactor and can be used for a variety of applications, including depositing and etching materials on a wafer W. For example, the deposition apparatus 100 may be used for chemical vapor deposition (CVD), plasma-enhanced CVD (PECVD), atomic layer deposition (ALD), or the like. In some embodiments, the deposition apparatus 100 may perform an epitaxial growth on a surface of a wafer W. The deposition apparatus 100 may include a reaction chamber 110, a susceptor 120, a gas passage 130, a gas exhaust passage 140, a gas baffle structure 150, a shower plate 160, and a susceptor ring 170.

The reaction chamber 110 is surrounded by a chamber wall 112. In some embodiments, the chamber wall 112 may be made of a rigid material (e.g., stainless steel) that can support the reaction chamber 110 against external pressure caused by at least partial vacuum. The chamber wall 112 may be covered by liners made of material that is inert to the process gas in the deposition process. For example, the liners are made of quartz. In some embodiments, the chamber wall 112 indicate the positions of the liners. The susceptor 120 is located in the reaction chamber 110. The reaction chamber 110 can be a sealed enclosure where a controlled process occurs. The susceptor 120 is a rigid plate configured to support and hold a wafer W during the deposition process. The susceptor 120 may be formed of metal, plastic, ceramic, and/or another hard material that supports the wafer W. In some embodiments, the susceptor 120 may have a shape that is at least partially concave relative to an axis parallel to the susceptor 120. The susceptor 120 may be heated to a high temperature and located within a susceptor environment that is at least a partial vacuum during the deposition process. In the context, for better illustration, a combination of the susceptor 120 and the wafer W are labelled to as a susceptor structure 120′.

In FIG. 1A, a shaft SH supports the susceptor 120 from below. The shaft SH may be formed of metal, plastic, other rigid materials that can support the susceptor 120. The susceptor 120 may rotate during the deposition process, for example, a rotational motor may be used to rotate the shaft SH and the susceptor 120, thereby producing a uniform distribution of reactants on the wafer W on the susceptor 120. The shaft SH and the rotational motor in combination can be referred to as a rotation assembly or a support assembly. In some embodiments, the susceptor ring 170 may be disposed around the susceptor 120 for reducing leakage of the reactant gas. The susceptor ring 170 may be a dielectric liner, such as a silicon carbide liner.

The gas passage 130 and the gas exhaust passage 140 are connected to the reaction chamber 110 and on opposite sides of the reaction chamber 110. Gas lines IL fluidly connect the gas passage 130 to one or more reactant gas sources 212, optionally one or more dopant gas sources 214, and optionally a carrier gas source 220. The reactant gas sources 212 may store reactant gas, such as semiconductor-containing reactant gas (e.g., semiconductor-containing precursors) and H₂. The dopant gas sources 214 may store dopant gas, such as n-type dopant gas (e.g., phosphorus-containing gas) or a p-type dopant gas. The carrier gas source 220 may store carrier gas (e.g., nitrogen gas and/or H₂). Through the configuration, a process gas PG containing the reactant gases from the reactant gas sources 212 and the dopant gas from the dopant gas sources 214 can be introduced to the reaction chamber 110 during deposition process. The carrier gas CG can also be introduced to the reaction chamber 110 during deposition process. The dopant gas may be omitted from the process gas PG in some embodiments. In some embodiments, an extension direction of the gas passage 130 may be substantially aligned with a top surface of the susceptor 120 and/or the wafer W, such that the process gas PG can flow into the reaction chamber 110 along a substantially horizontal direction (e.g., a direction substantially parallel to the top surface of the wafer W). The gas passage 130 may be referred to as a gas inlet in some embodiments.

In some embodiments of the present disclosure, the gas baffle structure 150 is in the reaction chamber 110 and between the gas passage 130 and the susceptor 120. The gas baffle structure 150 may surround the susceptor 120. The gas baffle structure 150 is made of material that is inert to the process gas PG in the deposition process. For example, the gas baffle structure 150 may be made of a metal material, a dielectric material, the like, or the combination thereof. The gas baffle structure 150 has a portion 152 near the gas passage 130. The portion 152 of the gas baffle structure 150 is configured to block a flow of the process gas PG from the gas passage 130 to the susceptor 120 along the substantially horizontal direction (e.g., a direction substantially parallel to the top surface of the wafer W) and direct the process gas PG to flow upward. For example, a bottom end of the portion 152 of the gas baffle structure 150 is lower than an imaginary center line 130C of the gas passage 130, or even lower than a lower inner wall 130L of the gas passage 130.

In some embodiments of the present disclosure, the shower plate 160 is in the reaction chamber 110 and above the susceptor 120, the gas passage 130, and the gas exhaust passage 140. The shower plate 160 may be supported by the gas baffle structure 150. The shower plate 160 is made of material that is inert to the process gas PG in the deposition process. For example, the shower plate 160 may be made of quartz, ceramics, the like, or the combination thereof. The shower plate 160 is configured to distribute the process gas PG to a surface of the wafer W. The intended direction of gas flow within the reaction chamber 110 is from top to bottom through the shower plate 160. For example, the shower plate 160 has plural holes 160O thereon. The shower plate 160 may be a plate located in a direction substantially parallel to a top surface of the susceptor 120 and/or the wafer W, and the shower plate 160 bisects the reaction chamber 110 into a upper region 110S1 over the shower plate 160 and a lower region 110S2 below the shower plate 160. The holes 160O allow the process gas PG in the region 110S1 over the shower plate 160 to flow through themselves to the region 110S2 below the shower plate 160, thereby reaching a surface of the wafer W. Through the configuration of the shower plate 160, the process gas PG can flow through the shower plate 160 onto the wafer W in the reaction chamber 120 along a direction substantially perpendicular to a top surface of the wafer W. In some embodiments, the shower plate 160 may be referred to as a showerhead or a gas distribution plate.

A height between the shower plate 160 and the susceptor 120 (or the wafer W) may be in a range from about 1 centimeter to about 25% of a diameter of the susceptor 120 (or the wafer W). If the height between the shower plate 160 and the susceptor 120 (or the wafer W) is greater than about 25% of a diameter of the susceptor 120 (or the wafer W), the flow is susceptible to form recirculation that cause instability in the laminar flow. If the height between the shower plate 160 and the susceptor 120 (or the wafer W) is less than about 1 centimeter, it may cause some chamber mechanical issues (e.g., thermal expansion issues, other particle issues). In some embodiments, the shower plate 160 may be in contact with the portion 152 of the gas baffle structure 150 for reducing gas leakages.

In the present embodiments, the holes 160O of the shower plate 160 can be spatially uniformly arranged (e.g., equidistantly arranged) in a circular shape. The circular shape filled with the holes 160O may have a size equal to or greater than a size of the susceptor 120. For example, a radius of the circular shape is equal to or greater than a radius of the susceptor 120. In some embodiments, the circular shape may overlap an edge of the susceptor 120. Through the configuration, the shower plate 160 may uniformly dispense the process gas PG to different regions of the wafer W. The holes 160O of the shower plate 160 may be arranged according to process requirement in some other embodiments.

After the process gas PG flows over the wafer W to cause epitaxial growth, an exhaust gas EG including unreacted gases and by-products may exit the reaction chamber 110 through the gas exhaust passage 140. The gas exhaust passage 140 may be inserted into the chamber 110. For example, the gas exhaust passage 140 may be fluidly coupled to a gas exhaust system 300, through an exhaust line EL. The gas exhaust system 300 may include a pump or a vacuum source in some embodiments. In some embodiments, an extension direction of the gas exhaust passage 140 may be substantially aligned with the top surface of the susceptor 120 and/or the wafer W, such that the exhaust gas EG can flow into the gas exhaust passage 140 along a substantially horizontal direction (e.g., the direction substantially parallel to the top surface of the wafer W). The gas baffle structure 150 allows the exhaust gas EG to flow to the gas exhaust passage 140. The gas baffle structure 150 has a portion 154 near the gas exhaust passage 140. For example, a bottom end of the portion 154 of the gas baffle structure 150 is higher than an imaginary center line 140C of the gas exhaust passage 140, or even higher than an upper inner wall 140U of the gas exhaust passage 140. Thus, the gas baffle structure 150 does not block the exhaust gas EG from the gas exhaust passage 140. The portion 154 of the gas baffle structure 150 may be in contact with the shower plate 160 for reducing leakage of the reactant gas. In some embodiments, the portion 154 of the gas baffle structure 150 may be in contact with the chamber wall 112 for reducing leakage of the reactant gas. In the present embodiments, the imaginary center line 130C of the gas passage 130 is substantially aligned and parallel to the imaginary center line 140C of the gas exhaust passage 140. In some other embodiments, the imaginary center line 130C of the gas passage 130 can be higher than or lower than the imaginary center line 140C of the gas exhaust passage 140.

FIG. 1C is a schematic view of a portion of a deposition apparatus according to some embodiments of the present disclosure. Reference is made to FIGS. 1A-1C. The gas baffle structure 150 has an inlet window 150W1 allowing the process gas PG to flow to the region 110S1 over the shower plate 160, and an outlet window 150W2 allowing the exhaust gas EG to flow away from the region 110S2 below the shower plate 160 (e.g, away from the susceptor structure 120′). The outlet window 150W2 may be opposite to the inlet window 150W1. The inlet window 150W1 may be referred to as an inject port or an inlet for the region 110S1, while the outlet window 150W2 may be referred to as an exhaust port or an outlet for the region 110S2. For clear illustration, directions X, Y, Z are labelled in FIG. 1C, in which the directions X and Y are substantially parallel with the top surface of the susceptor structure 120′ (e.g., susceptor 120 and/or the wafer W), and the direction Z is substantially normal to the top surface of the susceptor structure 120′ (e.g., susceptor 120 and/or the wafer W). The gas passage 130 and the gas exhaust passage 140 may be aligned with each other along the direction X in some embodiments. With the presence of the gas baffle structure 150, the process gas PG from the gas passage 130 is directed upward to a region 110S1 over the shower plate 160, and then flows from the region 110S1 over the shower plate 160 to the region 110S2 below the shower plate 160 through the holes 160O, thereby reaching the wafer W. The deposition process may use the process gas PG in the region 110S2 to interact with a semiconductor material of the wafer. After the deposition process, the exhaust gas EG is directed away from wafer W without being blocked by the gas baffle structure 150. The portions 152 and 154 of the gas baffle structure 150 are illustrated as connected in the drawings. In some other embodiments, the portions 152 and 154 of the gas baffle structure 150 are respectively two separate gas baffle structures for blocking and directing the flow of the process gas PG and the flow of the exhaust gas EG, respectively.

In some embodiments, the deposition process performed on the wafer W (such as a CVD process step) may use heat to trigger and control epitaxial growth on the wafer W. Accordingly, one or more heating elements that is capable of generating heat (e.g., using an electric current or other form of convection) may be positioned around the susceptor structure 120′ to maintain a temperature of the wafer W during the processing step. In some embodiments, the susceptor 120 of the susceptor structure 120′ may include the one or more heating elements. Use of heating elements allows the deposition apparatus 100 to operate in a cold wall/hot substrate mode. Stated differently, the deposition apparatus 100 in FIG. 1A is a “cold wall” reactor. That is, the chamber wall 112 is at a substantially lower temperature than a top surface of the susceptor 120 of the susceptor structure 120′ (where the wafer W placed thereon) during the deposition processing. In some embodiments, the susceptor ring 170 may include the one or more heating elements. Thus, the chamber wall 112 is at a substantially lower temperature than both the susceptor ring 170 and the top surface of the susceptor 120 during the deposition processing. For example, in a process to deposit an epitaxial silicon film on a wafer, the susceptor structure 120′ are heated to a temperature ranging from about 400° C. to about 1200° C., while the chamber wall 112 may be at a temperature ranging from about 150° C. to about 600° C. depending on the cooling efficiency. The chamber wall 112 are at a cooler temperature because they do not receive direct heat from the heating elements, and because cooling fluid is circulated through the chamber wall 112.

In absence of the gas baffle structure 150 and the shower plate 160, the process gas is introduced to the reaction chamber along the substantially horizontal direction (e.g., the direction substantially parallel to the top surface of the wafer W), the vector of the inject process gas flow may be coplanar with the vectors of a rotation-induced gas flow. Therefore, it is possible to form a stagnant zone with recirculating flow (e.g., a vortex) around it. Massless particles (e.g., precursors) can get trapped in the vortex, and be held above the wafer for extended duration even after the source injection is cut off. The rotation induced gas velocity will dominate that of the horizontal cross flow velocity, and the strength of the vortex may depend on wafer rotation speed and the cross-flow rate. And, instability in the laminar flow caused by the recirculating flow would impact process uniformity.

In some embodiments of the present disclosure, by re-directing the flow of the process gas PG to become vertical, the vector of the flow of the inject process gas PG is not co-planar with the vectors of the flow of the rotation-induced gas RG. FIG. 2 shows vectors of flows of the process gas PG and the rotation-induced gas RG during a deposition process according to some embodiments of the present disclosure. For example, the vector of the flow of the inject process gas PG is substantially orthogonal to the vectors of the flow of the rotation-induced gas RG. Through the configuration, a swirling flow, not a vortex, may be formed. And, process uniformity can be improved by omitting instable laminar flows.

In some embodiments, in some simulation results, by re-directing the flow of the process gas PG to become vertical, the residence time of particles on the wafer W may not depend strongly on a ratio of an inject velocity of the inject process gas PG to a rotation velocity of the rotation-induced gas RG. As a result, the residence time of particles on the wafer W is almost independent of inject velocity of the inject process gas PG.

In some embodiments, the simulation results may show a residence time of particles at a wafer center is greater than a residence time of particles at a wafer edge. The patterns of the holes 160O of the shower plate 160 can be adjusted for achieving desired residence time of particles at the wafer center and desired residence time of particles at the wafer edge. For example, the holes 160O of the shower plate 160 near the center of the shower plate 160 can be reduced as illustrated in FIG. 1D, thereby reducing a difference of the residence time of particles at the wafer center and the residence time of particles at the wafer edge.

Reference is made back to FIG. 1A. The deposition apparatus 100 may include a controller 400 electrically connected with the heating elements for adjusting the temperature of the wafer W. The controller 400 may also be electrically connected with control the flow controller V1 coupled to the gas lines IL, the flow controller V2 coupled to the gas lines EL, and the gas exhaust system 300 for controlling and adjusting a chamber pressure of the reaction chamber 110 and a velocity of gas flows (e.g., a velocity of laminar flows). The flow controllers V1 and V2 are configured to control the flow of gases, and the flow controllers V1 and V2 can be mass flow controllers (MFC), gas valves or any other suitable flow controlling elements. The controller 400 may include a computer-readable storage medium and a processor coupled to the computer-readable storage medium. The computer-readable storage medium stores program that controls various steps of the deposition method performed in the deposition apparatus 100. The controller 400 controls the operations of the deposition apparatus 100 by using the processor reading out and executing the program stored in the storage medium. The program may be one that has been stored in the computer-readable storage medium, or may be one that has been installed to the storage medium of the controller 400.

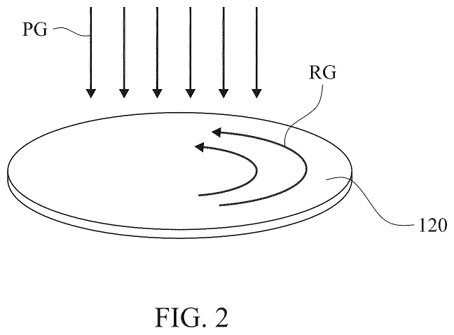

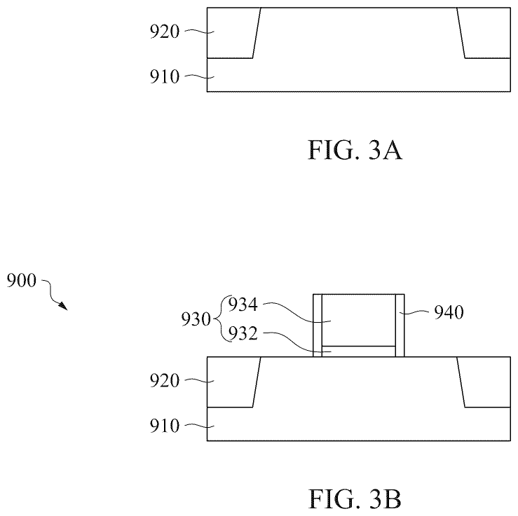

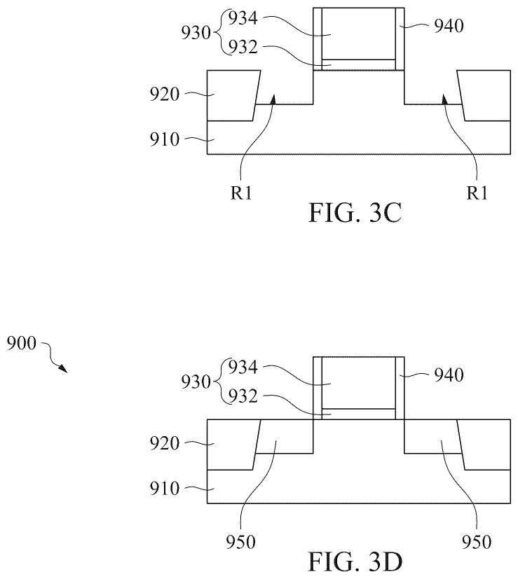

FIGS. 3A-3D are schematic cross-sectional views of a semiconductor device during various stage of manufacture according to some embodiments of the present disclosure. It is understood that additional steps may be provided before, during, and after the steps shown in FIGS. 3A-3D, and some of the steps described below can be replaced or eliminated for additional embodiments of the method. The order of the operations/processes may be interchangeable.

Reference is made to FIG. 3A. A substrate 910 is provided. The substrate 910 may be a bulk silicon substrate. Alternatively, the substrate 910 may include an elementary semiconductor, such as silicon (Si) or germanium (Ge) in a crystalline structure; a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb); or combinations thereof.

Isolation structures 920 are formed over the substrate 910 and defining an active region of the substrate 910. In some embodiments, the isolation structures 920 may act as a shallow trench isolation (STI) around a semiconductor fin. The isolation structures 920 may be formed by depositing a dielectric material into trenches in the substrate 910. In some embodiments, the dielectric material may include silicon oxide, silicon nitride, silicon oxynitride, fluorine-doped silicate glass (FSG), a low-k dielectric, combinations thereof, and/or other suitable materials. In various examples, the dielectric material may be deposited by a CVD process, a subatmospheric CVD (SACVD) process, a flowable CVD process, an ALD process, a physical vapor deposition (PVD) process, and/or other suitable process. In some embodiments, after deposition of the dielectric material, a chemical mechanical polishing (CMP) process may be performed to remove an excess portion of the dielectric material, and remaining portion of the dielectric material form the isolation structures 920.

Reference is made to FIG. 3B. A gate structure 930 is formed over the active region of the substrate 910. In some embodiments, the gate structure 930 includes a gate dielectric 932 and a gate electrode 934 over the gate dielectric 932. The gate electrode 934 may include polycrystalline-silicon (poly-Si) or poly-crystalline silicon-germanium (poly-SiGe). Further, the gate electrode 934 may be doped poly-silicon with uniform or non-uniform doping. The gate dielectric 932 may include, for example, a high-k dielectric material such as metal oxides, metal nitrides, metal silicates, transition metal-oxides, transition metal-nitrides, transition metal-silicates, oxynitrides of metals, metal aluminates, zirconium silicate, zirconium aluminate, or combinations thereof. In some embodiments, the gate structure 930 may be formed by, for example, forming a stack of a gate dielectric layer and a gate electrode layer over the substrate 910, followed by patterning the stack of the gate dielectric layer and the gate electrode layer. The patterning process may include a suitable photolithography process and a suitable etching process.

Gate spacers 940 may be formed alongside sidewalls of the gate structure 930. The formation of the gate spacers 940 may include conformally depositing a spacer layer over the gate structures 930 and the substrate 910, followed by an anisotropic etching process. The anisotropic etching process may remove horizontal portions of the spacer layer and remain vertical portions of the spacer layer, which form the gate spacers 940. The spacer layer may be deposited by suitable processes such as, CVD process, an ALD process, a PVD process, or other suitable process. The gate spacers 940 may include a dielectric material such as SiO₂, SION, SiCON, SiCO, the like, and/or combinations thereof.

Reference is made to FIG. 3C. Portions of the active region of the substrate 910 uncovered the gate structure 930 and the gate spacers 940 may be recessed by one or more suitable etching processes. The recessing process may include a dry etch, a wet etch, or the combination thereof. The etching process may use suitable etchants, such that the gate structure 930 and the gate spacers 940 may serve as etch masks during the etching process and protect the underlying active region of the substrate 910 from being removed. And, the isolation structures 920 may not substantially be etched by the etching process. After the recessing process, recesses R1 are formed in the active region of the substrate 910.

Reference is made to FIG. 3D. Source/drain epitaxial structures 950 are respectively formed over the recessed portions of the active region of the substrate 910 (e.g., in the recesses R1). In some embodiments, the source/drain epitaxial structures 950 may also be referred to as epitaxy features. The source/drain epitaxial structure 950 may be formed using one or more epitaxy or epitaxial (epi) processes, such that one or more semiconductor materials can be formed in a crystalline state on the semiconductor substrate 910. The source/drain epitaxial structures 950 may include a suitable semiconductor material, such as germanium (Ge) or silicon (Si); or compound semiconductor materials, such as silicon carbide (SiC). The source/drain epitaxial structures 950 may include one or plural epitaxial layers, in which the plural epitaxial layers may have different compositions. The deposition apparatus illustrated in FIGS. 1A and 1B may be used to form the source/drain epitaxial structures 950.

The epitaxy processes include CVD deposition techniques (e.g., vapor-phase epitaxy (VPE) and/or ultra-high vacuum CVD (UHV-CVD)), molecular beam epitaxy, and/or other suitable processes. The epitaxy process may use gaseous precursors, which interact with the composition of a semiconductor material (e.g., the semiconductor substrate 910). The source/drain epitaxial structures 950 may be in-situ doped.

In the illustrated embodiments, the source/drain epitaxial structures 950 are n-type epitaxial structures which may include a suitable semiconductor material, such as germanium (Ge) or silicon (Si); or compound semiconductor materials, such as silicon carbide (SiC), being doped with n-type dopants, such as phosphorus or arsenic. For example, the source/drain epitaxial structures 950 are silicon doped with phosphorus (Si:P). In some embodiments, the source/drain epitaxial structures 950 may have a n-type dopant concentration (e.g., phosphorus concentration) greater than about 10¹⁸ atoms/cm³, or even greater than about 2×10²¹ atoms/cm³. In some alternative embodiments, the source/drain epitaxial structures 950 may be p-type epitaxial structures, which may include a suitable semiconductor material, such as germanium (Ge) or silicon (Si); or compound semiconductor materials, and doped with p-type dopants, such as boron or BF₂.

In some embodiments of the present disclosure, for achieving the high dopant concentration (e.g., high phosphorus concentration in the n-type source/drain epitaxial structures 950), the deposition apparatus 100 (referring to FIG. 1A) is operated at a low-flow and high-pressure condition for depositing process. For example, the deposition apparatus 100 is operated at a partial vacuum condition with a chamber pressure in a range from about 50 torr to about 760 torr, with a rotation speed of the susceptor 120 or the wafer W in a range from about 5 rmp to about 300 rpm, and with a flow velocity that the process gas PG is introduced into the chamber in a range from about 1 slm to about 20 slm, in which the flow velocity depends on a chamber housing a wafer with a suitable size, and a chamber process with a suitable volume. With the configuration, a flow velocity of the laminar flow in the reaction chamber 110 on the wafer surface may be achieved, which allows the source/drain epitaxial structures 950 to be deposited with a high dopant concentration. For example, the flow velocity of the laminar flow in the reaction chamber 110 on the wafer surface may be lower than about 0.03 meters per second, or even lower than about 0.01. If the chamber pressure is less than about 30 torr and/or the flow velocity that the process gas PG is introduced into the chamber is less than 1 slm, the dopant concentration of the epitaxy feature may not be high enough for source/drain epitaxial structures, and process controllability will be poor as it will be like a closed chamber. If the chamber pressure is greater than about 500 torr and/or the flow velocity that the process gas PG is introduced into the chamber is greater than 50 slm, it is difficult to control the profile and dopant profile of the epitaxy feature since the deposition rate may be too fast, and process controllability will be poor at too high pressure due to side effects such as gas phase reactions and particle. If the rotation speed is greater than about 80 rpm, the flow velocity of the laminar flow may become too high (e.g., greater than 0.03 meters per second) to deposit the epitaxy feature with a high dopant concentration, and flow instability may occur around the edge. If the rotation speed is lower than about 5 rpm, the epitaxy features may not be deposited uniformly over the wafer W. The chamber pressure and the flow velocity of the laminar flow in the reaction chamber 110 can be controlled by the controller 400. After the epitaxial growth, one or more annealing processes may be performed to activate the source/drain epitaxial structures 950. The annealing processes may include rapid thermal annealing (RTA) and/or laser annealing processes.

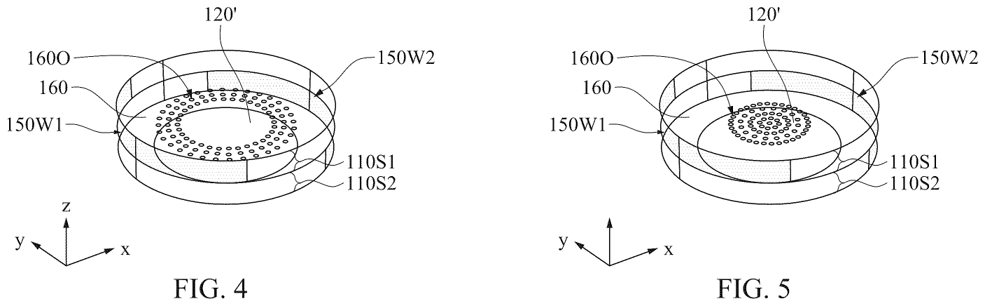

FIG. 4 is a schematic view of a portion of a deposition apparatus according to some embodiments of the present disclosure. Details of the present embodiments are similar to that of FIGS. 1A-1D, except that the holes 160O of the shower plate 160 are uniformly arranged (e.g., equidistantly arranged) in a ring shape. In some embodiments, the ring shape may overlap an edge of the susceptor structure 120′. For example, the ring shape filled with the holes 160O may have an inner radius less than a radius of the susceptor structure 120′ (e.g., susceptor 120) and an outer radius greater than the radius of the susceptor structure 120′ (e.g., susceptor 120). Other details of the present embodiments are similar to those illustrated in FIGS. 1A-1D, and therefore not repeated herein.

FIG. 5 is a schematic view of a portion of a deposition apparatus according to some embodiments of the present disclosure. Details of the present embodiments are similar to that of FIGS. 1A-1D, except that the circular shape filled with the holes 160O may have a size less than a size of the susceptor structure 120′ (e.g., susceptor 120). For example, a radius of the circular shape is less than a radius of the susceptor structure 120′ (e.g., susceptor 120). Other details of the present embodiments are similar to those illustrated in FIGS. 1A-1D, and therefore not repeated herein.

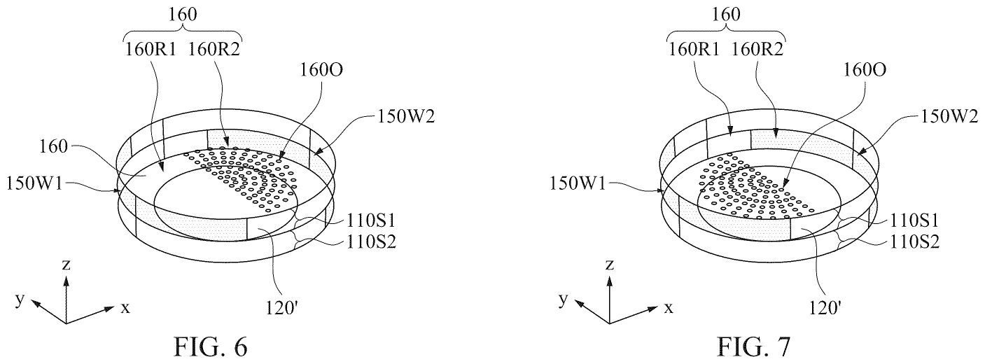

FIG. 6 is a schematic view of a portion of a deposition apparatus according to some embodiments of the present disclosure. Details of the present embodiments are similar to that of FIGS. 1A-1D, except that the holes 160O of the shower plate 160 are uniformly arranged (e.g., equidistantly arranged) in a semi-circular shape. The semi-circular shape filled with the holes 160O is adjacent to the outlet window 150W2 and away from the inlet window 150W1. Stated differently, when viewed from top (e.g., along the direction Z), the shower plate 160 has a first region 160R1 free of any holes 160O and a second region 160R2 having holes 160O, and the second region 160R2 is between the first region 160R1 and the gas exhaust passage 140 (referring to FIG. 1A). In some embodiments, the semi-circular shape may overlap an edge of the susceptor structure 120′ (e.g., susceptor 120). The circular shape filled with the holes 160O may have a size equal to or greater than a size of the susceptor structure 120′ (e.g., susceptor 120). For example, a radius of the circular shape is equal to or greater than a radius of the susceptor structure 120′ (e.g., susceptor 120). Other details of the present embodiments are similar to those illustrated in FIGS. 1A-1D, and therefore not repeated herein.

FIG. 7 is a schematic view of a portion of a deposition apparatus according to some embodiments of the present disclosure. Details of the present embodiments are similar to that of FIG. 6, except that the semi-circular shape filled with the holes 160O is adjacent to the inlet window 150W1 and away from the outlet window 150W2. Stated differently, when viewed from top (e.g., along the direction Z), the shower plate 160 has a first region 160R1 having holes 160O and a second region 160R2 free of any holes 160O, and the second region 160R2 is between the first region 160R1 and the gas exhaust passage 140 (referring to FIG. 1A). Other details of the present embodiments are similar to those illustrated in FIG. 6, and therefore not repeated herein.

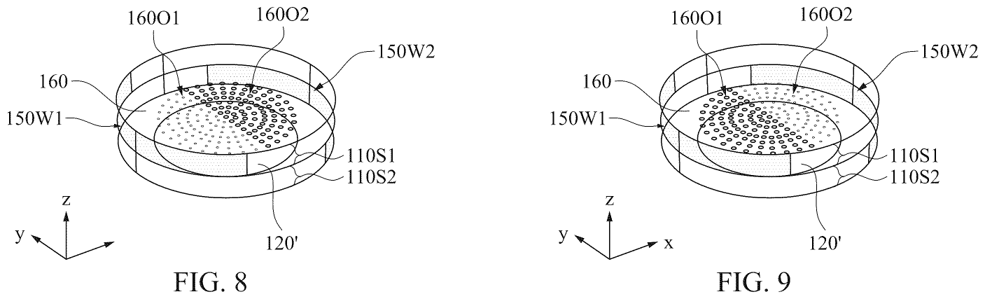

FIG. 8 is a schematic view of a portion of a deposition apparatus according to some embodiments of the present disclosure. Details of the present embodiments are similar to that of FIGS. 1A-1D, except that the shower plate 160 has holes 160O1 and 160O2, and the holes 160O1 and 160O2 have different sizes. For example, the holes 160O1 adjacent to the inlet window 150W1 have a size less than the size of the holes 160O2 adjacent to the outlet window 150W2. Stated differently, when viewed from top (e.g., along the direction Z), the holes 160O2 is between the holes 160O1 and the gas exhaust passage 140 (referring to FIG. 1A), and the size of the holes 160O2 is greater than the size of the holes 160O1. In the present embodiments, the holes 160O1 are uniformly arranged (e.g., equidistantly arranged) in a semi-circular shape adjacent to the inlet window 150W1 and away from the outlet window 150W2. And, the holes 160O2 are uniformly arranged (e.g., equidistantly arranged) adjacent to the outlet window 150W2 and away from the inlet window 150W1. In the present embodiments, Other details of the present embodiments are similar to those illustrated in FIGS. 1A-1D, and therefore not repeated herein.

FIG. 9 is a schematic view of a portion of a deposition apparatus according to some embodiments of the present disclosure. Details of the present embodiments are similar to that of FIG. 8, except that the size of the holes 160O1 adjacent to the inlet window 150W1 is greater than the size of the holes 160O2 adjacent to the outlet window 150W2. Stated differently, when viewed from top (e.g., along the direction Z), the holes 160O2 is between the holes 160O1 and the gas exhaust passage 140 (referring to FIG. 1A), and the size of the holes 160O2 is less than the size of the holes 160O1. Other details of the present embodiments are similar to those illustrated in FIG. 8, and therefore not repeated herein.

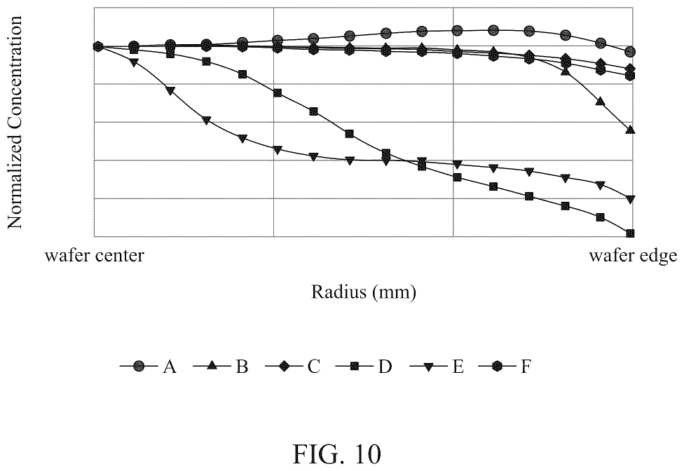

FIG. 10 is a diagram illustrating relative gas concentration distributions on a wafer according to some embodiments of the present disclosure. The horizontal axis represents a position from a wafer center to a wafer edge. The vertical axis represents a normalized gas concentration of particles. Lines A, B, C, D, E, F indicates the behavior using the deposition apparatus including the shower plate 160 with different hole patterns shown in FIGS. 4-9, respectively. As shown in FIG. 10, for the lines B, D, and E, gas concentrations at the wafer center are higher than gas concentrations at the wafer edge. For the lines A, C, and F, gas concentrations may be uniformly distributed over the wafer center and the wafer edge.

It is evidenced from FIGS. 4-10 that designing the holes of the shower plate 160 with different patterns (e.g., different sizes and distribution) would cause various reactor flow characteristics. Therefore, it can be concluded that the patterns of the holes of the shower plate 160 (e.g., sizes and distribution of the holes of the shower plate 160) can be optimized for achieving specific reactor flow characteristics. In some examples, for achieving a target reactor flow characteristic, the pattern of the holes of the shower plate 160 (e.g., sizes and distribution of the holes of the shower plate 160) can be determined as a function of the chamber parameters/conditions (e.g., a position of the inlet window 150W1 of the gas baffle structure 150, a position of the outlet window 150W2 of the gas baffle structure 150, a height from the wafer W to the shower plate 160, a height of the reaction chamber 110, and a diameter of the reaction chamber 110 (referring to FIG. 1A)) and/or other process parameters/conditions.

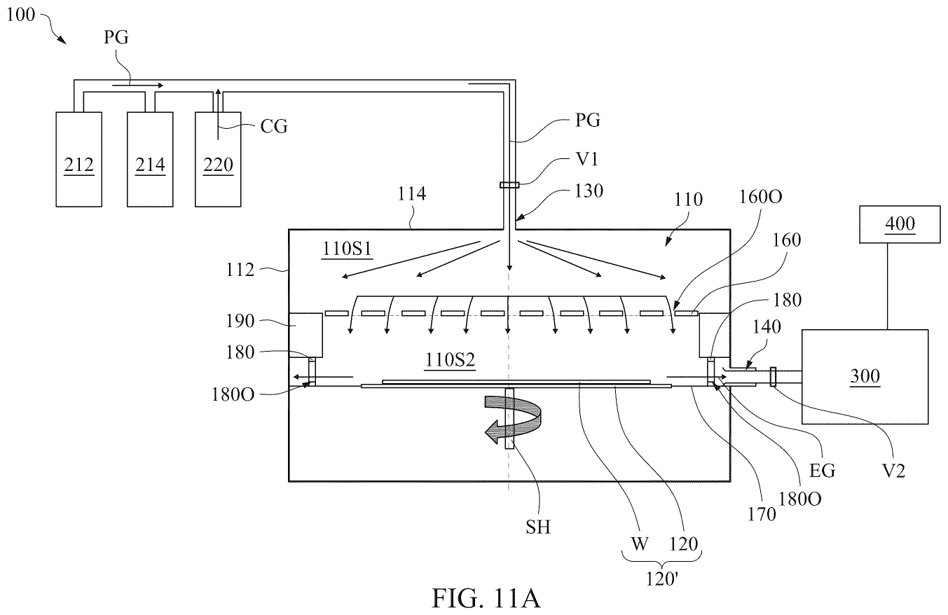

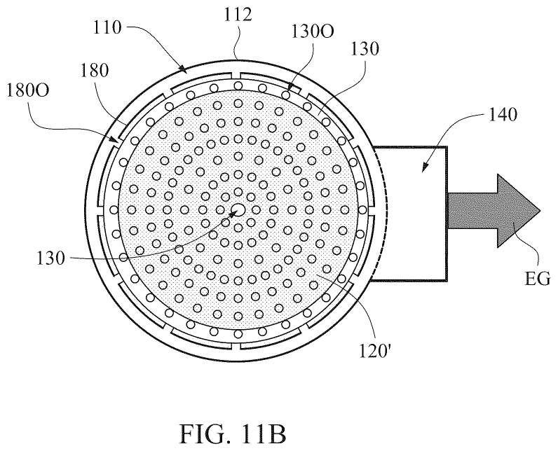

FIG. 11A is a schematic cross-sectional view of a deposition apparatus 100 according to some embodiments of the present disclosure. FIG. 11B is a schematic top view of the deposition apparatus of FIG. 11A. Details of the present embodiments are similar to that of FIGS. 1A-1D, except that the process gas PG flows into the reaction chamber 110 along a direction substantially normal to the top surface of the wafer W. For example, the gas passage 130 is located at a ceiling 114 of the reaction chamber 110 and above the shower plate 160. In some embodiments, a quartz dome may serve as the ceiling 114 of the reaction chamber 110, and the gas passage 130 may be a gas inlet fed through the quartz dome. With this configuration, the process gas PG from the gas passage 130 is directed downward to a region 110S1 over the shower plate 160, and then flows from the region 110S1 over the shower plate 160 to the region 110S2 below the shower plate 160 through the holes 160O, thereby reaching the wafer W. The deposition process may use the process gas PG to interact with a semiconductor material of the wafer.

In the present embodiments, the deposition apparatus 100 may include a gas exhaust structure 180 surrounding the susceptor structure 120′ (e.g., susceptor 120) to improve the uniformity of the removal of the exhaust gas EG. The gas exhaust structure 180 is made of material that is inert to the process gas PG in the deposition process. For example, the gas exhaust structure 180 may be made of a metal material, a dielectric material, the like, or the combination thereof. The gas exhaust structure 180 may be referred to as an exhaust ring, which is a solid ring with vent holes (e.g., openings/orifices 1800) bored through from inner to outer surface. The openings/orifices 1800 of the gas exhaust structure 180 are fluidly connected with the gas exhaust passage 140 to allow the exhaust gas EG pass. With the presence of the gas exhaust structure 180, the exhaust gas EG can be directed away from wafer W through the openings/orifices 1800 of the gas exhaust structures 180 in various different directions after the deposition process. The openings/orifices 1800 of the gas exhaust structure 180 can form an arc of variable length, optimizable in tandem with the pattern of the holes of the shower plate 160 (e.g., sizes and distribution of the holes of the shower plate 160). This arrangement can free up the liner at the inlet side for more symmetric exhaust port configuration.

In some embodiments, the deposition apparatus 100 may include a supporting structure 190 in the reaction chamber 110 and configured to support the shower plate 160. The supporting structure 190 is made of material that is inert to the process gas PG in the deposition process. For example, the supporting structure 190 may be made of a metal material, a dielectric material, the like, or the combination thereof. The supporting structure 190 is omitted in the top view of FIG. 11B. Other details of the present embodiments are similar to those illustrated in FIGS. 1A-1D, and therefore not repeated herein.

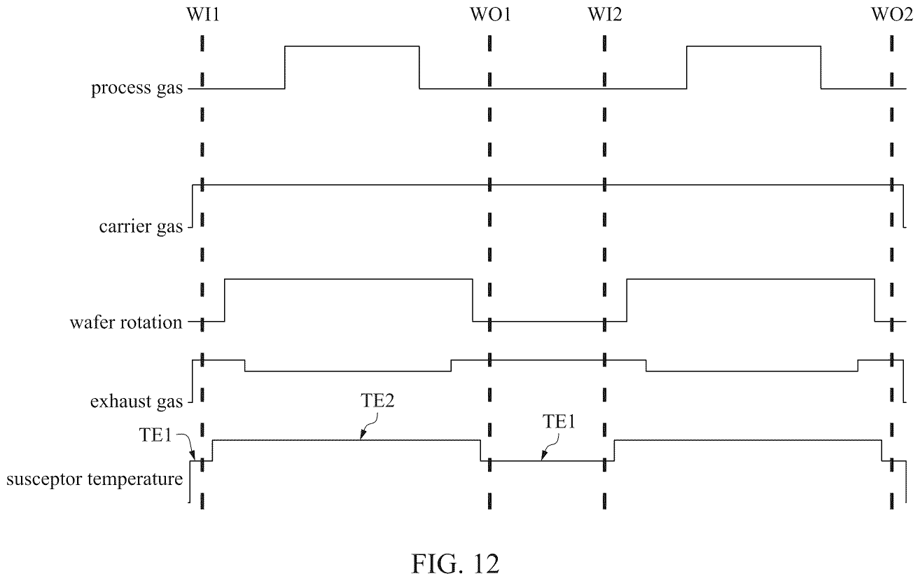

FIG. 12 shows pulses versus time in a deposition process according to some embodiments of the present disclosure. Reference is made to FIGS. 1A and 11A. Four dashed bold lines WI1, WO1, WI2, WO2 are used to indicate the timing of wafer transfer. The dashed bold line WI1 indicates the timing when a first wafer W is loaded into the reaction chamber 110 and placed on the susceptor 120. The dashed bold line WO1 indicates the timing when the first wafer W is removed from the susceptor 120 and unloaded from the reaction chamber 110. The dashed bold line WI2 indicates the timing when a second wafer W is loaded into the reaction chamber 110 and placed on the susceptor 120. The dashed bold line WO2 indicates the timing when the second wafer W is removed from the susceptor 120 and unloaded from the reaction chamber 110. In some embodiments, in regardless of the wafer load or unload, the carrier gas CG is kept being introduced into the reaction chamber 110, the susceptor 120 is heated and kept at a first temperature TE1, and the gas exhaust system 300 (e.g., the pump) and/or the flow controller V2 are controlled to remove an exhaust gas EG from the reaction chamber 110.

The time interval between the dashed bold lines WI1 and WO1 (or the time interval between the dashed bold lines WI2 and WO2) indicates the steps/pulses for a deposition process. For each wafer W, after the wafer W is loaded into the reaction chamber 110 (as indicated by the dashed bold lines WI1 and WI2), the susceptor 120 may rotate the wafer W and heat the wafer W to a second temperature TE2 higher than the first temperature TE1. The first temperature TE1 and the second temperature TE2 are simply shown as constant in the drawing for ease illustration. In some practical examples, the first temperature TE1 and the second temperature TE2 can vary over time according to the chamber condition, and the second temperature TE2 is higher than the first temperature TE1. Subsequently, the gas exhaust system 300 (e.g., the pump) and/or the flow controller V2 are controlled to adjust the exhaust gas EG exiting from the reaction chamber 110, thereby providing a high-pressure condition (e.g., a suitable pressure greater than about 100 torr and below about 1 atm) in the reaction chamber 110. Then, the process gas PG is introduced through the gas passage 130 into the reaction chamber 110, for example, by the control of the flow controller V1. As aforementioned, the process gas PG is distributed by the shower plate 160 onto the wafer W to interact with the wafer W, thereby epitaxially growing an epitaxy feature on the wafer W. The wafer W is heated and rotated when the process gas PG is distributed by the shower plate 160. To end the epitaxial growth, the process gas PG is stopped from being introduced into the reaction chamber 110, for example, by the control of the flow controller V1. Subsequently, the gas exhaust system 300 (e.g., the pump) and/or the flow controller V2 are controlled to adjust the exhaust gas EG from the reaction chamber 110. Then, the susceptor 120 may stop heating and rotating the wafer W, such that a temperature of the susceptor 120 or the wafer W falls back to the first temperature TE1. After that, the wafer W is unloaded from the reaction chamber 110 (as indicated by the dashed bold lines WO1 and WO2).

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that by re-directing the flow of the process gas to become vertical, the vector of the flow of the inject gas is not co-planar with the vectors of the flow of the rotation-induced gas, thereby avoiding a stagnant zone with recirculating flow (e.g., a vortex) around it, and a swirling flow may be formed. Another advantage is that with the re-directed vertical flow, the residence time of particles on the wafer is almost independent of inject velocity. Still another advantage is that patterns of the holes of the shower plate (e.g., sizes and distribution of the holes of the shower plate) can be optimized for achieving specific reactor flow characteristics. Still another advantage is that a chamber of a horizontal reactor is designed with gas flow characteristics of a vertical reactor, thus achieving the functionality while maintaining cost advantage.

According to some embodiments of the present disclosure, a method includes introducing a semiconductor-containing precursor gas into a reaction chamber through a gas passage; directing the semiconductor-containing precursor gas from the gas passage to a region over a shower plate, wherein the shower plate is above the gas passage and a wafer in the reaction chamber; guiding the semiconductor-containing precursor gas to flow through the shower plate; rotating the wafer; and epitaxially growing an epitaxy feature over the wafer by using the semiconductor-containing precursor gas to interact with the wafer when rotating the wafer.

According to some embodiments of the present disclosure, a method includes rotating a wafer; introducing a process gas into a reaction chamber when rotating the wafer, wherein the process gas comprises a semiconductor-containing precursor gas and a dopant gas; guiding the process gas to flow through a shower plate onto a wafer in the reaction chamber along a direction substantially perpendicular to a top surface of the wafer; and epitaxially growing an epitaxy feature over the wafer by using the process gas to interact with the wafer when rotating the wafer.

According to some embodiments of the present disclosure, a deposition apparatus includes a reaction chamber; a susceptor in the reaction chamber; a shower plate above the susceptor; a gas passage connected to the reaction chamber; a gas source fluidly connected with the gas passage; a gas baffle structure having a first portion between the gas passage and the susceptor, wherein a bottom end of the first portion of the gas baffle structure is lower than a center line of the gas passage; and a gas exhaust passage below the shower plate and connected to the reaction chamber.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
introducing a semiconductor-containing precursor gas into a reaction chamber through a gas passage;
directing the semiconductor-containing precursor gas from the gas passage to a region over a shower plate, wherein the shower plate is above the gas passage and a wafer in the reaction chamber;
guiding the semiconductor-containing precursor gas to flow through the shower plate;
rotating the wafer; and
epitaxially growing an epitaxy feature over the wafer by using the semiconductor-containing precursor gas to interact with the wafer when rotating the wafer.

2. The method of claim 1, further comprising:
introducing a dopant gas into the reaction chamber through the gas passage.

3. The method of claim 2, wherein the dopant gas comprises phosphorus.

4. The method of claim 1, wherein a temperature of the wafer is higher than a temperature of a chamber wall of the reaction chamber when epitaxially growing the epitaxy feature.

5. The method of claim 1, wherein introducing the semiconductor-containing precursor gas into the reaction chamber through the gas passage is performed such that the semiconductor-containing precursor gas flows along a direction substantially parallel with a top surface of the wafer.

6. The method of claim 5, wherein directing the semiconductor-containing precursor gas to the region over the shower plate comprising:
using a gas baffle structure, stopping the semiconductor-containing precursor gas from flowing to the top surface of the wafer along the direction substantially parallel with the top surface of the wafer.

7. The method of claim 1, further comprising:
directing an exhaust gas between the shower plate and the wafer to an exhaust passage below the shower plate.

8. The method of claim 7, wherein directing the exhaust gas to the exhaust passage is performed such that the exhaust gas flows along a direction substantially parallel with a top surface of the wafer.

9. A method, comprising:
rotating a wafer;
introducing a process gas into a reaction chamber when rotating the wafer, wherein the process gas comprises a semiconductor-containing precursor gas and a dopant gas;
guiding the process gas to flow through a shower plate onto the wafer in the reaction chamber along a direction substantially perpendicular to a top surface of the wafer; and
epitaxially growing an epitaxy feature over the wafer by using the process gas to interact with the wafer when rotating the wafer.

10. The method of claim 9, wherein introducing the process gas is performed through a gas passage above the shower plate.

11. The method of claim 9, further comprising:
directing an exhaust gas between the shower plate and the wafer to an exhaust passage below the shower plate.

12. The method of claim 11, wherein directing the exhaust gas between the shower plate and the wafer to the exhaust passage comprising:
directing the exhaust gas to flow through a plurality of openings of a gas exhaust structure surrounding the wafer.

13. The method of claim 11, wherein directing the exhaust gas between the shower plate and the wafer to the exhaust passage is performed when rotating the wafer.

14. A deposition apparatus, comprising:
a reaction chamber;
a susceptor in the reaction chamber;
a shower plate above the susceptor;
a gas passage connected to the reaction chamber;
a gas source fluidly connected with the gas passage;
a gas baffle structure having a first portion between the gas passage and the susceptor, wherein a bottom end of the first portion of the gas baffle structure is lower than a center line of the gas passage; and
a gas exhaust passage below the shower plate and connected to the reaction chamber.

15. The deposition apparatus of claim 14, wherein the gas passage is below the shower plate.

16. The deposition apparatus of claim 15, wherein the gas baffle structure has a second portion near the gas exhaust passage, a bottom end of the second portion of the gas baffle structure is higher than a center line of the gas exhaust passage.

17. The deposition apparatus of claim 14, wherein the shower plate having a plurality of first holes and a plurality of second holes, wherein a size of the second holes is less than a size of the first holes, and the first holes are between the second holes and the gas passage when viewed from top.

18. The deposition apparatus of claim 14, wherein the shower plate having a plurality of first holes and a plurality of second holes, wherein a size of the second holes is greater than a size of the first holes, and the first holes are between the second holes and the gas passage when viewed from top.

19. The deposition apparatus of claim 14, wherein the shower plate having a first region having a plurality of holes and a second region free of any holes, and the first region is between the second region and the gas passage when viewed from top.

20. The deposition apparatus of claim 14, wherein the shower plate having a first region free of any holes and a second region having a plurality of holes, and the first region is between the second region and the gas passage when viewed from top.
